(19) United States
(12) Patent Application Publication
(10) Pub. No.: US 2006/0220208 A1
(43) Pub. Date: Oct. 5, 2006

(54) Stacked-type semiconductor device and method of manufacturing the same

(76) Inventors: Masanori Onodera, Kawasaki (JP); Kouichi Meguro, Kawasaki (JP); Junichi Kasai, Kawasaki (JP)

Correspondence Address: INGRASSIA FISHER & LORENZ, P.C., 7150 E. CAMELBACK, STE. 325, SCOTTSDALE, AZ, 85251, US

(21) Appl. No.: 11/394,986

(22) Filed: Mar. 30, 2006

Related U.S. Application Data
(63) Continuation of application No. PCT/JP05/06264, filed on Mar. 31, 2005.

(51) Int. Cl. H01L 23/02

(52) U.S. Cl. 257/686

(57) ABSTRACT

A semiconductor device of a stacked type includes a semiconductor chip (1) that is mounted on a substrate (4), a first sealing resin (12) that seals the semiconductor chip (1), a built-in semiconductor device (9) that is placed on the first sealing resin (12), and a second sealing resin (13) that is formed on the substrate (4) and seals the semiconductor chip (1) and the built-in semiconductor device (9). In this semiconductor device, the semiconductor chip (1) and the built-in semiconductor device (9) are electrically connected to the substrate by bonding wires (3).

### CROSS-REFERENCES TO RELATED APPLICATIONS

This is a continuation of International Application No. PCT/JP2005/006264, filed Mar. 31, 2005 which was not published in English under PCT Article 21(2).

### BACKGROUND OF THE INVENTION

1. Field of the Invention

The present invention relates to a stacked-type semiconductor device that has two or more semiconductor devices contained in a package, and to a method of manufacturing the stacked-type semiconductor device.

2. Description of the Related Art

In recent years, mobile electronic devices such as portable telephone devices and non-volatile storage media such as IC memory cards have become smaller. In line with this trend, there is an increasing demand for a reduction in the number of components of such devices and media, as well as a demand for a reduction in size.

Therefore, development of a technique for efficiently packaging semiconductor chips that are essential components of those devices is strongly desired.

Examples of such packages that satisfy the above demand include chip scale packages (CSP) that have almost the same size as semiconductor chips, multi-chip packages (MCP) each having two or more semiconductor chips contained in a package, and stacked-type packages such as package-on-package (PoP) structures, each having two or more packages combined into one. FIG. 1 illustrates a MCP structure, and FIG. 2 illustrates a PoP structure. In the package-on-package structure, the lower package and the upper package are electrically connected to each other via solder balls, as shown in FIG. 2, and the resin sealing portion of the lower package is molded with a metal mold.

In a case where two or more semiconductor chips (bare chips) are to be contained in one package, a complex package having two or more packages integrated is more advantageous in terms of yield than a MCP having two or more chips stacked directly on one another, depending on the yield of each semiconductor chip formed in the wafer. This is because, in a MCP, even one defective chip makes the entire package also defective and hinders reuse of the other non-defective chips, while in a complex package, only non-defective packages are combined to form a package.

Japanese Unexamined Patent Publication No. 2003-282814 discloses a semiconductor device having a package-in-package (PiP) structure as an example of a complex package. In this semiconductor device, a package is included in a package. More specifically, a package (a built-in semiconductor device 10) that has solder balls 6 and has been determined to be a non-defective package through a test is included in a package, as shown in FIG. 3. A chip 9 is mounted on the built-in package, and is connected to an interposer 4 with wires 3.

In the case where a package having bumps formed thereon is to be contained in a package, the following problems are caused during the manufacturing process. The first problem is that a semiconductor device contained in a semiconductor device is mounted on a substrate via the solder bumps. In such a case, the distance between the contained semiconductor device and the substrate is as short as several tens of microns. Therefore, when the distance is filled with a sealing resin in the sealing step, insufficient filling is often caused or a void is often formed. Another resin material (an underfill material) may be applied to the space between the contained semiconductor device and the substrate in advance. With this arrangement, however, it is difficult to maintain stable quality at a low cost.

The second problem is that the heat transfer path for transferring heat from the substrate to the semiconductor device is limited to the solder bumps existing in the space between the substrate and the semiconductor device. Especially, in a case where the distance between the substrate and each wire connecting pad on the built-in package is long, heat is not readily transferred from the substrate to the pads. As a result, it becomes difficult to maintain a temperature high enough for wire bonding. Also, with the structure having two interposers wire-bonded respectively to the two semiconductor chips, it is difficult to produce a thin package.

### SUMMARY OF THE INVENTION

It is therefore an object of the present invention to provide a stacked-type semiconductor device and a method of manufacturing the stacked-type semiconductor device in which the above disadvantages are eliminated.

A more specific object of the present invention is to provide a semiconductor device of a stacked type with stable quality at a low cost, and a method of manufacturing such a semiconductor device.

The above objects of the present invention are achieved by a semiconductor device of a stacked type that includes a semiconductor chip that is mounted on a substrate, a first sealing resin that seals the semiconductor chip, a built-in semiconductor device that is placed on the first sealing resin, and a second sealing resin that is formed on the substrate and seals the semiconductor chip and the built-in semiconductor device. In this semiconductor device, the semiconductor chip and the built-in semiconductor device are electrically connected to the substrate by bonding wires. In this package structure, external connecting terminals such as solder bumps do not exist between the built-in semiconductor device and the substrate. Accordingly, sealing with the second sealing resin can be readily performed. Furthermore, as the built-in semiconductor device is placed directly on the first sealing resin, the heat transfer path becomes wider than that of the prior art. Thus, wire bonding can be stably performed.

In this semiconductor device, the built-in semiconductor device may be placed on the top surface of the first sealing resin and has an area equal to or smaller than the area of the top surface. Since the area of the built-in semiconductor device is equal to or smaller than the area of the top surface of the first sealing resin, the heat can be easily transferred from the first sealing resin and wire bonding can be readily performed.

In this semiconductor device, the built-in semiconductor device may be a semiconductor chip or a package in which a semiconductor chip is packaged. As a semiconductor chip or a semiconductor device not having an interposer is used as the built-in semiconductor device, the number of substrates used is reduced. Thus, the packaging cost can also be reduced.

In this semiconductor device, the built-in semiconductor device may have flat electrodes on a top surface thereof, and the bonding wires are connected to the flat electrodes. With the flat electrodes being formed on the built-in semiconductor device, the connection of the built-in semiconductor device on the first sealing resin to the substrate with the bonding wires becomes easier. Also, as the flat electrodes are located above the first sealing resin, the allowable range in the wire bonding conditions, especially the load and temperature conditions, becomes advantageously wider.

In this semiconductor device, the electrodes may have an uppermost layer containing aluminum, palladium, or tin. Since the uppermost layer of the electrodes on the built-in semiconductor device contains aluminum, palladium, or tin, electrical connection between the substrate and the built-in semiconductor device can be established by wire bonding.

In this semiconductor device, the first sealing resin and the built-in semiconductor device may be bonded by a paste or film of an electrically conductive adhesive. With the electrically conductive adhesive, the temperature of the built-in semiconductor device can readily be increased and defective wire bonding or the like can be prevented. Particularly, with a film-like adhesive agent, the maximum parallelism can be maintained in the semiconductor device.

In this semiconductor device, the built-in semiconductor device may have a reallocation wiring layer. As connection is established with the reallocation wiring layer, the wire bonding becomes easier.

The above objects of the present invention are also achieved by a method of fabricating a semiconductor device of a stacked type that includes the steps of electrically connecting pads on a substrate and a semiconductor chip formed thereon by wires, sealing the semiconductor chip with a first sealing resin, mounting a built-in semiconductor device on a top surface of the first sealing resin, electrically connecting pads on the substrate and the built-in semiconductor device by wires, and sealing, on the substrate, the built-in semiconductor device and the semiconductor chip with a second sealing resin. In this package structure, external connection terminals such as solder bumps do not exist between the built-in semiconductor device and the substrate. Accordingly, sealing with the second sealing resin can be readily performed. Furthermore, as the built-in semiconductor device is placed directly on the first sealing resin, the heat transfer path becomes wider than that of the prior art. Thus, wire bonding can be stably performed. Also, as the area of the built-in semiconductor device is equal to or smaller than the area of the top surface of the first sealing resin located below the built-in semiconductor device, heat can easily be transferred from the first sealing resin. Thus, wire bonding can be readily performed.

As described above, the present invention can provide a semiconductor device of a stacked type with stable quality at a low cost. The present invention can also provide a method of fabricating such a semiconductor device.

### BRIEF DESCRIPTION OF THE DRAWINGS

FIG. 1 is a cross-sectional view of a conventional semiconductor device of a stacked type having a multi-chip package (MCP) structure;

FIG. 2 is a cross-sectional view of a conventional semiconductor device of a stacked type having a package-on-package (PoP) structure;

FIG. 3 is a cross-sectional view of a conventional semiconductor device of a stacked type having a package-in-package (PiP) structure;

FIG. 4 is a cross-sectional view of a semiconductor device of a stacked type having a semiconductor chip as a built-in semiconductor device in accordance with a first embodiment of the present invention;

FIG. 5 illustrates a modification of the first embodiment illustrated in FIG. 4;

FIG. 6 is a flowchart of the process of manufacturing the stacked-type semiconductor device illustrated in FIG. 4;

FIGS. 7A through 7E illustrate the procedures for manufacturing the stacked-type semiconductor device illustrated in FIG. 4;

FIG. 8 illustrates a semiconductor device of a stacked type in which a built-in semiconductor device is formed with a semiconductor chip, wherein the sealing resin is formed by metal molding, in accordance with a second embodiment of the present invention;

FIG. 9 illustrates a semiconductor device of a stacked type in which a built-in semiconductor device is formed with a semiconductor chip and wiring is acheived by reverse bonding in accordance with a third embodiment of the present invention;

FIG. 10 illustrates a semiconductor device of a stacked type in which a built-in semiconductor device is formed with two stacked semiconductor chips in accordance with a fourth embodiment of the present invention;

FIG. 11 illustrates a semiconductor device of a stacked type in which a built-in semiconductor device is a resin-sealed package in accordance with a fifth embodiment of the present invention;

FIG. 12 illustrates a semiconductor device of a stacked type in which a built-in semiconductor device is a resin-sealed package and the sealing resin is formed by metal molding in accordance with a sixth embodiment of the present invention;

FIG. 13 illustrates a semiconductor device of a stacked type in which a built-in semiconductor device is formed with a resin-sealed package and wiring is performed by reverse bonding in accordance with a seventh embodiment of the present invention; and

FIG. 14 illustrates a semiconductor device of a stacked type in which a built-in semiconductor device is a wafer-level CSP in accordance with an eighth embodiment of the present invention.

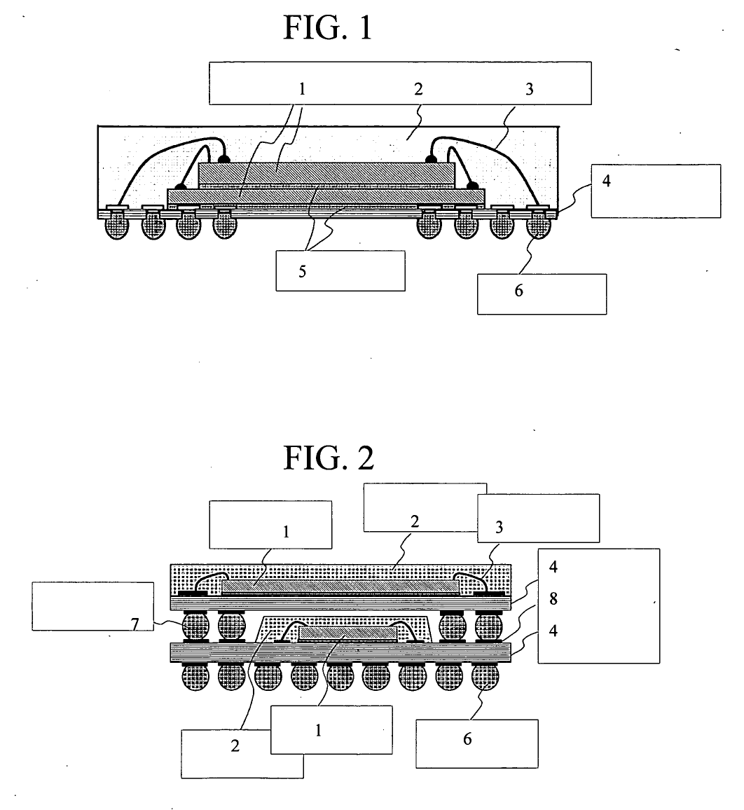

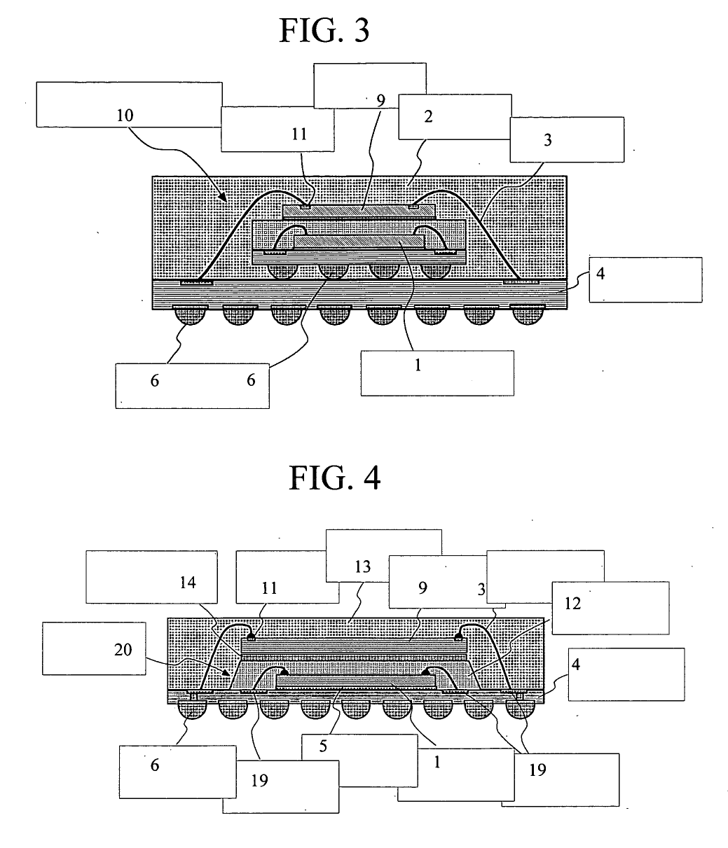

### DESCRIPTION OF THE PREFERRED EMBODIMENTS

The following is a description of preferred embodiments of the present invention, with reference to the accompanying drawings.

### First Embodiment

Referring first to FIG. 4, the structure of a first embodiment of the present invention is a semiconductor device of a stacked type that has a ball grid array and contains a semiconductor chip as a built-in semiconductor device. In the package, a lower package 20 and a chip 9 as a built-in semiconductor device are stacked. The lower package 20 has a semiconductor chip 1 that is mounted on a substrate 4 and is sealed with a first sealing resin 12. The chip 9 is bonded onto the first sealing resin 12 with an electrically conductive adhesive 14. The semiconductor chip 1 is mounted on the substrate 4, with a die bonding material 5 being interposed between the semiconductor chip 1 and the substrate 4. The semiconductor chip 1 is connected to electrodes 19 on the substrate 4 with wires.

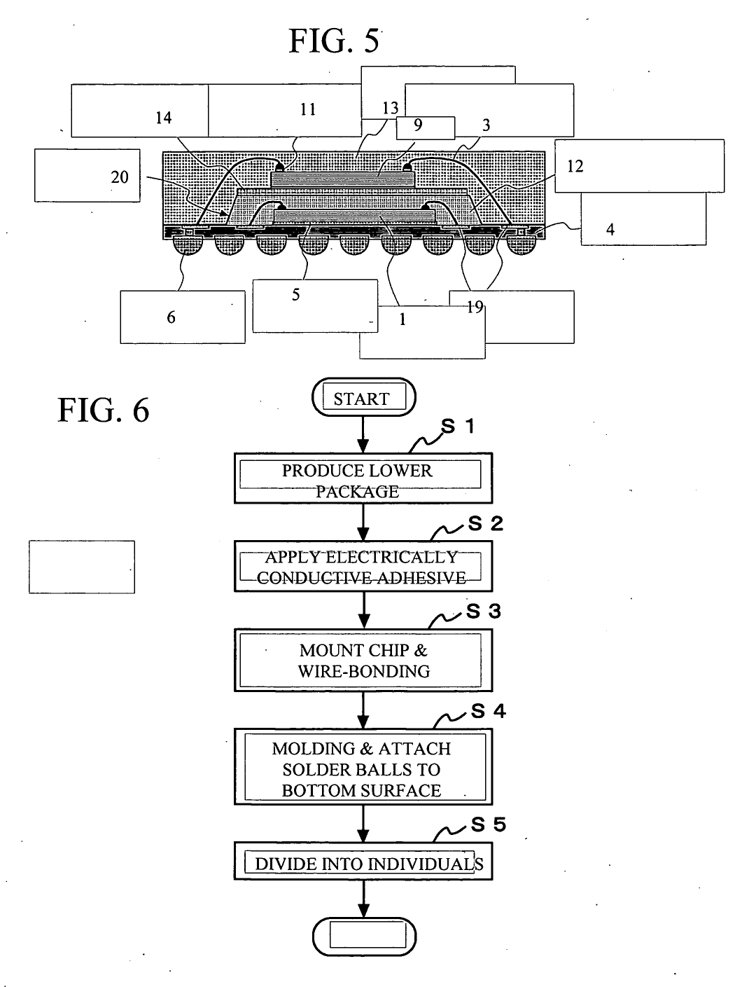

The lower package 20 is molded into a trapezoid with a metal mold. The area of a section that is taken in the direction parallel to the substrate 4 is smaller, as the section is farther away from the substrate 4. The chip 9 is mounted on the first sealing resin 12 of the trapezoid. The area of the chip 9 is equal to or smaller than the area of the top surface of the first sealing resin 12. FIG. 5 illustrates a case where the area of the chip 9 is smaller than the area of the first sealing resin 12. Since the area of the chip 9 is equal to or smaller than the area of the top surface of the first sealing resin 12, heat is readily transferred from the first sealing resin 12 and the wire bonding connecting the chip 9 to the substrate 4 can be performed with relative ease.

The first sealing resin 12 and the chip 9 are bonded to each other with the electrically conductive adhesive 14. The electrically conductive adhesive 14 is a paste or film made of a conductive material. With an adhesive agent of a conductive material, the temperature of the chip 9 can be readily increased, and defective wire bonding or the like can be prevented. Examples of the conductive material include an epoxy adhesive agent such as a silver paste or a silicon adhesive agent. Particularly, in a case where two or more chips 9 or packages are stacked on the first sealing resin 12, a film-type adhesive agent should preferably be used so as to maximize the parallelism between the chips 9 or packages.

In the case where the chip 9 is mounted on the first sealing resin 12, aluminum is generally used for electrode pads 11.

As the electrode pads 11 are located immediately above the first sealing resin 12, the allowable range of the wire bonding conditions, especially the load and temperature conditions, advantageously becomes wider.

The semiconductor device having the chip 9 placed on the lower package 20 is sealed with a second sealing resin 13. Solder balls 6 are formed on the bottom surface of the substrate 4. The stacked-type semiconductor device illustrated in FIG. 4 is resin-molded with a large-sized mold. More specifically, semiconductor devices having the lower packages 20 and the chips 9 stacked thereon are arranged on the substrate 4, and electric connection is established between the substrate 4 and the semiconductor devices. The semiconductor devices are collectively molded, and are then divided into individual semiconductor devices.

In such a package structure, the distance created by external connecting terminals such as solder balls does not exist between the substrate 4 and the chips 9 as built-in semiconductor devices. Accordingly, the molding with the second sealing resin 13 becomes relatively easy. Further, since the chips 9 as built-in semiconductor devices are bonded directly to the first sealing resin 12, the heat transfer path becomes wider and the wire bonding can be stably performed. Furthermore, as the semiconductor chips 1 on the lower side and the semiconductor chips 9 on the upper side are wire-bonded to the common interposer 4, the total height of the package can be reduced.

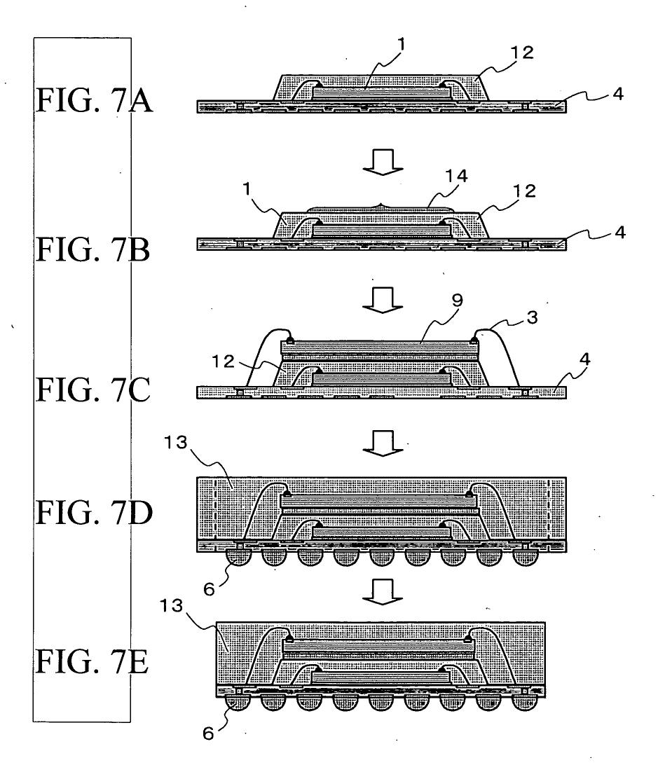

Referring now to FIG. 6 and FIGS. 7A through 7E, the procedures for manufacturing the above described semiconductor device of a stacked type is described. FIG. 6 is a flowchart showing the manufacturing process, and FIGS. 7A through 7E illustrate the respective manufacturing steps. First, the lower package 20 is formed (step S1). The semiconductor chip 1 is mounted on the substrate 4, and the substrate 4 and the semiconductor chip 1 are electrically connected by wire bonding. The semiconductor chip 1 is then sealed with the first sealing resin 12. FIG. 7A illustrates the lower package 20.

The electrically conductive adhesive 14 is then applied onto the first sealing resin 12 (step S2), and the chip 9 is mounted on the first sealing resin 12 (step S3). The area of the chip 9 is equal to or smaller than the area of the top surface of the first sealing resin 12. The chip 9 and the substrate 4 are connected by wire bonding (step S3). FIG. 7B illustrates the step of applying the electrically conductive adhesive onto the first sealing resin 12. FIG. 7C illustrates the step of mounting and bonding the chip 9 onto the first sealing resin 12 with wires.

Next, the chip 9 and the semiconductor chip 1 sealed with the first sealing resin 12 are sealed with the second sealing resin 13 (step S4). The solder balls 6 for external connection are connected to the bottom surface of the substrate 4. FIG. 7D illustrates this procedure. Lastly, collectively molded semiconductor devices of a stacked type are severed from one another (step S5), to produce the semiconductor device of a stacked type illustrated in FIG. 7E.

### Second Embodiment

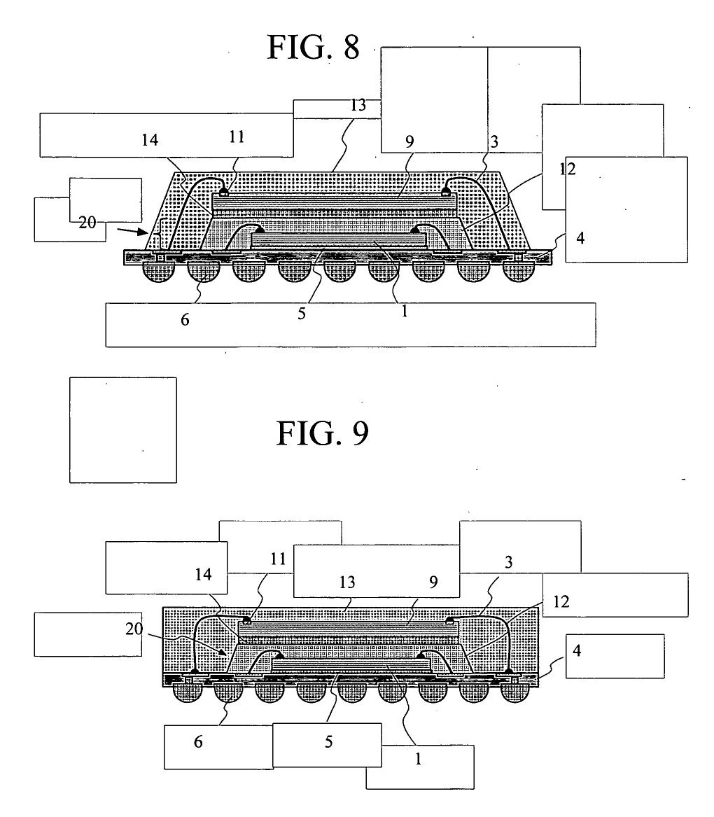

FIG. 8 illustrates a semiconductor device of a stacked type in accordance with a second embodiment of the present invention. In the stacked-type semiconductor device in accordance with the second embodiment illustrated in FIG. 8, a semiconductor chip is employed as a built-in semiconductor chip, and the second sealing resin 13 is metal-molded. With the stacked-type semiconductor device of this structure, the same effects as those of the first embodiment can be achieved.

### Third Embodiment

FIG. 9 illustrates a semiconductor device of a stacked type in accordance with a third embodiment of the present invention. In the stacked-type semiconductor device in accordance with the third embodiment illustrated in FIG. 9, a semiconductor chip is employed as a built-in semiconductor chip, and wires 15 connecting the electrode pads 11 of the chip 9 to the electrodes 19 on the substrate 4 are bonded by reverse bonding. During reverse bonding, the first bonding and the second bonding are performed in reverse order. The first bonding is performed on the substrate 4, and the second bonding is performed on the chip 9. The wires 15 can be arranged in parallel with the substrate 4, so that the height of the package can be reduced.

### Fourth Embodiment

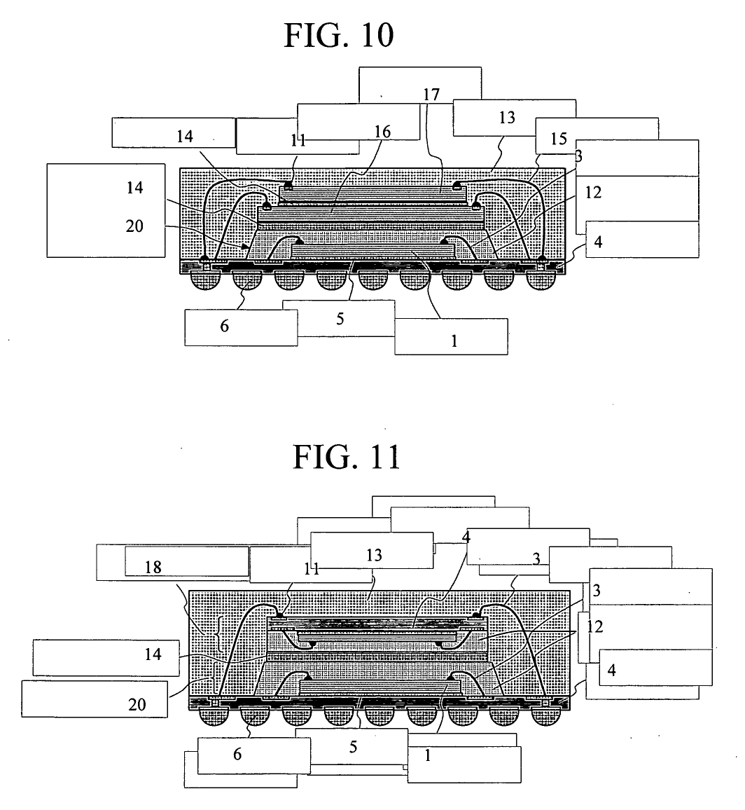

FIG. 10 illustrates a semiconductor device of a stacked type in accordance with a fourth embodiment of the present invention. In the stacked-type semiconductor device in accordance with the fourth embodiment illustrated in FIG. 10, two built-in semiconductor devices are stacked on a semiconductor chip. As shown in FIG. 10, a first chip 16 and a second chip 17 are stacked on the lower package 20. The first chip 16 and the second chip 17 are bonded to each other also with the electrically conductive adhesive 14. With this structure, the same effects as those of the first embodiment can be achieved.

### Fifth Embodiment

FIG. 11 illustrates a semiconductor device of a stacked type in accordance with a fifth embodiment of the present invention. In the stacked-type semiconductor device in accordance with the fifth embodiment illustrated in FIG. 11, a built-in semiconductor device is a resin-sealed package. In this structure, the upper package 18 also has a semiconductor chip 1 mounted on a substrate 4 and sealed with a first sealing resin 12. The first sealing resin 12 of the lower package 20 and the first sealing resin 12 of the upper package 18 are arranged to face each other and are bonded to each other with the electrically conductive adhesive 14. A resin-sealed package such as the lower package 20 or the upper package 18 may be a package of any type having electrodes on the top surface thereof. However, it is preferable to employ chip-size packages so as to reduce the size of the entire package. With packages that do not include a chip 9 or an interposer, the number of substrates used can be reduced from that of the prior art thereby reducing the packaging cost.

In the case where a package is mounted on the lower package 20, the electrode pads 11 are preferably formed by plating. In this case, gold, palladium, or tin (tin solder) is often used. The layer structure of the electrode pads 11 may be, for example, a multilayer structure formed by combining a copper plating layer and a nickel plating layer. In a case where a BGA or a chip-size package (CSP) is formed on the lower package 20, external electrodes such as solder balls that hinder the formation of a flat configuration are not formed, but the electrode pads 11 having flat shapes are arranged on the top surface of the upper package 18. With this arrangement, the substrate 4 and the electrode pads 11 can be wire-bonded to each other.

### Sixth Embodiment

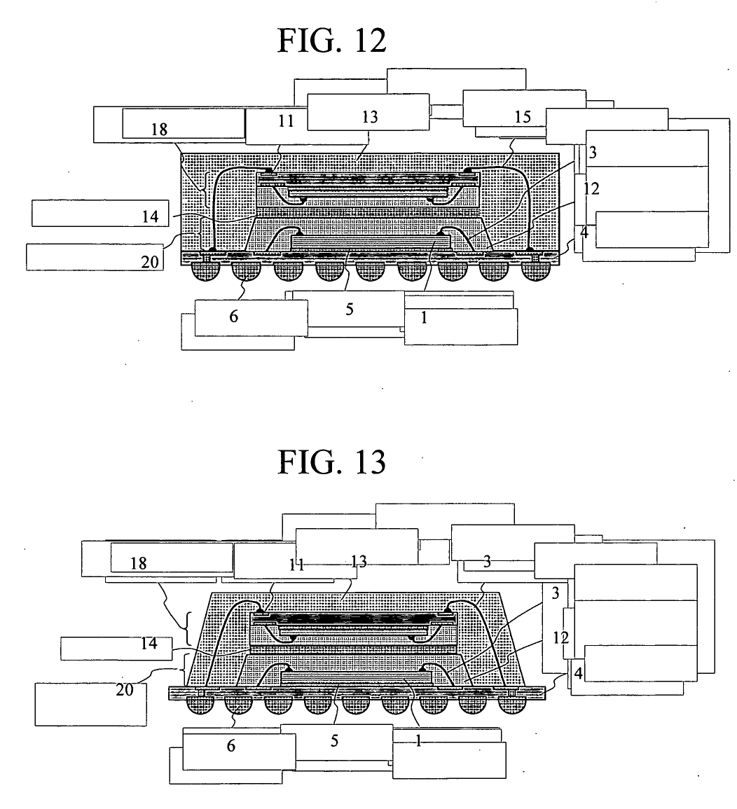

FIG. 12 illustrates a semiconductor device of a stacked type in accordance with a sixth embodiment of the present invention. In the stacked-type semiconductor device in accordance with the sixth embodiment illustrated in FIG. 12, the wires 15 connecting the upper package 18 and the substrate 4 are formed by reverse bonding. With this structure, the same effects as those of the first embodiment can be achieved.

### Seventh Embodiment

FIG. 13 illustrates a semiconductor device of a stacked type in accordance with a seventh embodiment of the present invention. In the stacked-type semiconductor device in accordance with the seventh embodiment illustrated in FIG. 13, the second sealing resin 13 of the fifth embodiment is formed in a trapezoid shape by metal molding.

### Eighth Embodiment

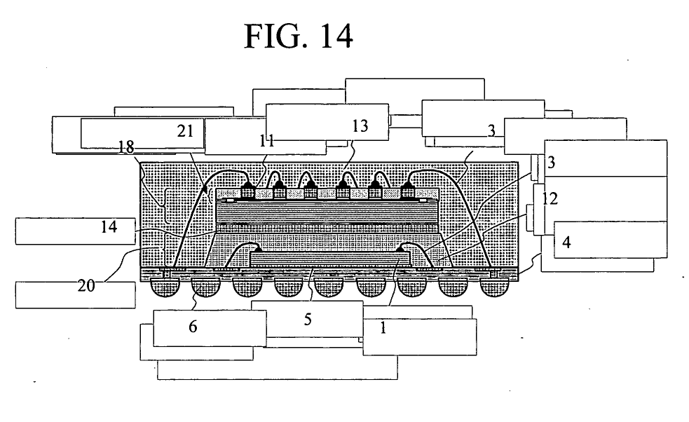

FIG. 14 illustrates a semiconductor device of a stacked type in accordance with an eighth embodiment of the present invention. In the stacked-type semiconductor device in accordance with the eighth embodiment illustrated in FIG. 14, a reallocation wiring layer 21 is provided in the upper package 18. The upper package 18 may be a wafer-level CSP, for example, with the chip surface being sealed with a polyimide insulating layer. External electrodes are also formed on the chip surface. The reallocation wiring layer 21 is formed on the insulating layer (a first sealing resin). The reallocation wiring layer 21 has a nickel film and a palladium film stacked on the top surfaces of copper plated pillars. With this reallocation wiring layer 21, the external electrodes of the upper package 18 are reallocated and flat electrode pads are provided. Thus, wire bonding can easily be performed.

Although a few preferred embodiments of the present invention have been shown and described, it would be appreciated by those skilled in the art that changes may be made in these embodiments without departing from the principles and spirit of the invention, the scope of which is defined in the claims below and their equivalents.

What is claimed is:

1. A semiconductor device of a stacked type, comprising:
a semiconductor chip that is mounted on a substrate;
a first sealing resin that seals the semiconductor chip;
a built-in semiconductor device that is placed on the first sealing resin; and
a second sealing resin that is formed on the substrate and seals the semiconductor chip and the built-in semiconductor device,
the semiconductor chip and the built-in semiconductor device being electrically connected to the substrate by bonding wires.

2. The semiconductor device as claimed in claim 1, wherein the built-in semiconductor device is placed on a top surface of the first sealing resin and has an area equal to or smaller than that of the top surface.

3. The semiconductor device as claimed in claim 1, wherein the built-in semiconductor device is a semiconductor chip or a package in which a semiconductor chip is packaged.

4. The semiconductor device as claimed in claim 1, wherein the built-in semiconductor device has flat electrodes on a top surface thereof, and wherein the bonding wires are connected to the flat electrodes.

5. The semiconductor device as claimed in claim 4, wherein the electrodes have an uppermost layer containing one or more of aluminum, palladium, and tin.

6. The semiconductor device as claimed in claim 1, wherein the first sealing resin and the built-in semiconductor device are bonded by a paste or film of an electrically conductive adhesive.

7. The semiconductor device as claimed in claim 1, wherein the built-in semiconductor device has a reallocation wiring layer.

8. A method of fabricating a semiconductor device of a stacked type, comprising the steps of:
electrically connecting pads on a substrate and a semiconductor chip formed thereon by wires;
sealing the semiconductor chip with a first sealing resin;
mounting a built-in semiconductor device on a top surface of the first sealing resin;
electrically connecting pads on the substrate and the built-in semiconductor device by wires; and
sealing, on the substrate, the built-in semiconductor device and the semiconductor chip with a second sealing resin.
